(19) United States
(12) Patent Application Publication
(10) Pub. No.: US 2025/0258245 A1
(43) Pub. Date: Aug. 14, 2025

(54) BATTERY DETERIORATION DETECTION DEVICE AND METHOD THEREOF

(71) Applicant: HYUNDAI MOBIS CO., LTD., Seoul (KR)

(72) Inventors: Hoon LEE, Yongin-si (KR); Dong Rak KIM, Yongin-si (KR); Won Hee LEE, Yongin-si (KR); Ji Ho LEE, Yongin-si (KR); Hong Jun LEE, Yongin-si (KR); Hyeon Been AN, Yongin-si (KR); Da Won GWAK, Yongin-si (KR)

(73) Assignee: HYUNDAI MOBIS CO., LTD., Seoul (KR)

(21) Appl. No.: 19/051,445

(22) Filed: Feb. 12, 2025

(30) Foreign Application Priority Data
Feb. 13, 2024 (KR) 10-2024-0020249

(51) Int. Cl. G01R 31/392; B60L 58/12; B60L 58/16; G01R 31/367; G01R 31/371; G01R 31/374; G01R 31/388

(52) U.S. Cl. CPC G01R 31/392; B60L 58/12; B60L 58/16; G01R 31/367; G01R 31/371; G01R 31/374; G01R 31/388

(57) ABSTRACT

A battery deterioration detection device, a method of operating a battery deterioration detection device, and a battery deterioration detection device for a vehicle are provided. The battery deterioration detection device includes a sensor to sense deterioration detection information of each of the cells included in a battery of the mobile device, an SOX estimator to generate an estimated value of each of the cells based on the deterioration detection information, a sequencer to determine whether to perform deterioration abnormal diagnosis on the battery based on at least one of the estimated value generated by the SOX estimator, an on or off state information of the battery, a stop holding time after the mobile device is stopped, and deterioration detection information of each of the cells, and a diagnoser to perform a deterioration abnormal diagnosis operation on the battery based on the diagnosis of the sequencer.

### CROSS-REFERENCE TO RELATED APPLICATION

The present application claims priority to and the benefit under 35 USC § 119 of Korean Patent Application No. 10-2024-0020249, filed Feb. 13, 2024, in the Korean Intellectual Property Office, the entire contents of which is incorporated herein for all purposes by this reference.

### BACKGROUND

### 1. Field of the Invention

Embodiments disclosed herein relate to a battery deterioration detection device and a method thereof.

### 2. Description of the Related Art

Recently, research and development on secondary batteries has been actively conducted. Here, the secondary battery is a battery capable of charging and discharging and includes all recent lithium ion batteries such as conventional Ni/Cd batteries and Ni/MH batteries. Among the secondary batteries, lithium-ion batteries have an advantage of having much higher energy density than conventional Ni/Cd batteries and Ni/MH batteries. In addition, the lithium-ion batteries may be made smaller and lighter and thus are used as a power source for mobile devices and recently, are attracting attention as next-generation energy storage media due to the expansion of the range of usage to a power source for electric vehicles.

In general, since these batteries deteriorate as they are used, it is necessary to accurately estimate a state of charge (SOC) and a state of health (SOH) of the deteriorated battery or to accurately determine the state of the battery for control of increasing the life of the deteriorated battery.

In particular, abnormal deterioration can cause an ignition problem. Accordingly, there is a need for a device and method for accurately estimating the state of the battery and detecting abnormal deterioration during initial operation of the battery.

### SUMMARY

Embodiments disclosed herein are directed to providing a battery deterioration detection device and a method thereof, in which it is possible to detect abnormal deterioration by accurately estimating a state of a battery.

Embodiments disclosed herein are also directed to providing a battery deterioration detection device and a method thereof, in which it is possible to detect abnormal deterioration by accurately estimating a state of a battery during initial operation of the battery.

Embodiments disclosed herein are also directed to providing a battery deterioration detection device and a method thereof, in which it is possible to prevent accidents due to thermal runaway by notifying a user of detected abnormal deterioration of a battery.

Technical objects of the embodiments disclosed herein are not limited to the above-described technical objects, and other objects that are not mentioned will be able to be clearly understood by those skilled in the art from the following descriptions.

In a general aspect of the disclosure, a battery deterioration detection device, includes: a sensor configured to sense deterioration detection information of each of a plurality of cells included in a battery of a mobile device; an SOX estimator configured to generate an estimated value of each of the plurality of cells based on the deterioration detection information; a sequencer configured to determine whether to perform deterioration abnormal diagnosis on the battery based on at least one of the estimated value generated by the SOX estimator, an on or off state information of the battery, a stop holding time after the mobile device is stopped, and deterioration detection information of each of the plurality of cells; and a diagnoser configured to perform a deterioration abnormal diagnosis operation on the battery based on the diagnosis of the sequencer.

The battery deterioration detection device may further include a display configured to display a result of performing the deterioration abnormal diagnosis operation by the diagnoser.

The display may be configured to, at least one of display a result of performing the deterioration abnormal diagnosis operation on each of the plurality of cells, or generate a group for the plurality of cells and display the result of performing the deterioration abnormal diagnosis operation through the group, or a combination thereof.

The deterioration detection information of each of the plurality of cells sensed by the sensor may include a voltage, current, and temperature of each of the plurality of cells.

The sequencer may be further configured to: determine that a maximum temperature of each of the plurality of cells is lower than or equal to a predefined maximum temperature and a minimum temperature of each of the plurality of cells is higher than or equal to a predefined minimum temperature in response to a determination that the stop holding time is greater than or equal to a predefined stop holding time; and determine the execution of deterioration abnormal diagnosis of the battery.

The estimated value generated by the SOX estimator may include at least one of a state of charge (SOC) and a state of health (SOH).

The diagnoser may generate an estimated open circuit voltage (OCV) value of each of the plurality of cells through a neural network model which receives the estimated value and temperature of each of the plurality of cells as an input.

The diagnoser may calculate a difference between the estimated OCV value and a voltage value sensed by the sensor and generates an estimated error value.

The diagnoser may receive the estimated error value and a predetermined threshold estimated error value and generate a result of performing the deterioration abnormal diagnosis operation on each of the plurality of cells in the battery.

In another general aspect of the disclosure, a method of operating a battery deterioration detection device, includes: sensing deterioration detection information of each of a plurality of cells included in a battery in a mobile device through a sensor; generating an estimated value of each of the plurality of cells based on the deterioration detection information through an SOX estimator; determining whether to perform deterioration abnormal diagnosis on the battery based on at least one of the estimated value generated by the SOX estimator, an on or off state information of the battery, a stop holding time after the mobile device is stopped, and deterioration detection information about each of the plurality of cells through a sequencer; performing a deterioration abnormal diagnosis operation on the battery based on the diagnosis of the sequencer through a diagnoser; and displaying a result of performing a deterioration abnormal diagnosis operation of the diagnoser through a display.

In yet another general aspect of the disclosure, a battery deterioration detection device for a vehicle, the battery detection device includes: a sensor to sense each of a plurality of cells included in a battery of the vehicle; an SOX estimator to generate an estimated value of each of the plurality of cells; a sequencer to determine whether to perform a deterioration abnormal diagnosis on the battery; a diagnoser to perform a deterioration abnormal diagnosis operation on the battery; and a controller configured to: control the sensor to sense deterioration detection information of each of the plurality of cells; control the SOX estimator to generate the estimated value of each of the plurality of cells based on the deterioration detection information; control the sequencer to determine whether to perform the deterioration abnormal diagnosis on the battery based on at least one of the estimated value generated by the SOX estimator, an on or off state information of the battery, a stop holding time after the vehicle is stopped, and deterioration detection information of each of the plurality of cells; and control the diagnoser to perform the deterioration abnormal diagnosis operation on the battery based on the diagnosis of the sequencer.

The battery deterioration detection device may further include a display, wherein the controller may be further configured to control the display to display a result of performing the deterioration abnormal diagnosis operation by the diagnoser.

The controller may be further configured to control the display to, at least one of display a result of performing the deterioration abnormal diagnosis operation on each of the plurality of cells, or generate a group for the plurality of cells and display the result of performing the deterioration abnormal diagnosis operation through the group, or a combination thereof.

The deterioration detection information of each of the plurality of cells sensed by the sensor may include a voltage, current, and temperature of each of the plurality of cells.

The controller may be further configured to control the sequencer to determine that a maximum temperature of each of the plurality of cells is lower than or equal to a predefined maximum temperature and a minimum temperature of each of the plurality of cells is higher than or equal to a predefined minimum temperature in response to a determination that the stop holding time is greater than or equal to a predefined stop holding time, and determine the execution of deterioration abnormal diagnosis of the battery.

The estimated value generated by the SOX estimator may include at least one of a state of charge (SOC) and a state of health (SOH).

The controller may be further configured to control the diagnoser to generate an estimated open circuit voltage (OCV) value of each of the plurality of cells through a neural network model which receives the estimated value and temperature of each of the plurality of cells as an input.

The controller may be further configured to control the diagnoser to calculate a difference between the estimated OCV value and a voltage value sensed by the sensor and generates an estimated error value.

The controller may be further configured to control the diagnoser to receive the estimated error value and a predetermined threshold estimated error value, and generate a result of performing the deterioration abnormal diagnosis operation on each of the plurality of cells in the battery.

### BRIEF DESCRIPTION OF THE DRAWINGS

FIG. 1 is a view illustrating a battery deterioration detection system according to one embodiment disclosed herein.

FIG. 2 is a block diagram showing a battery deterioration detection device according to one embodiment disclosed herein.

FIG. 3 is a conceptual diagram illustrating an operation flow between components of a battery deterioration detection device 100 according to one embodiment of this document.

FIG. 4 is a flowchart illustrating a method of operating a battery deterioration detection device according to one embodiment disclosed herein.

FIG. 5 is a view illustrating a method of operating a sequence unit according to one embodiment disclosed herein.

FIG. 6 is a view for describing an abnormal diagnosis block in a diagnosis unit according to one embodiment disclosed herein.

FIG. 7 is a view for describing a diagnosis unit including a plurality of abnormal diagnosis blocks according to one embodiment disclosed herein.

FIG. 8 is a view for describing a display unit according to one embodiment disclosed herein.

FIG. 9 is a view illustrating a computing system according to another embodiment disclosed herein.

### DETAILED DESCRIPTION

Hereinafter, embodiments disclosed herein will be described in detail with reference to exemplary drawings. In adding reference numerals to components in each drawing, it should be noted that the same components have the same reference numerals as much as possible even when they are illustrated in different drawings. In addition, in describing embodiments disclosed herein, the detailed description of related known configurations or functions will be omitted when it is determined that the detailed description obscures the understanding of the embodiments disclosed herein.

The terms, such as first, second, A, B, (a), and (b) may be used to describe components of the embodiments disclosed in this document. These terms are only for the purpose of distinguishing one component from another component, and the nature, sequence, order, or the like of the corresponding component is not limited by the terms. In addition, unless otherwise defined, all terms (including technical and scientific terms) used herein have the same meanings as those commonly understood by those skilled in the art to which embodiments disclosed herein pertains. The terms defined in a generally used dictionary should be construed as meanings that match with the meanings of the terms from the context of the related technology and are not construed as an ideal or excessively formal meaning unless clearly defined in this application.

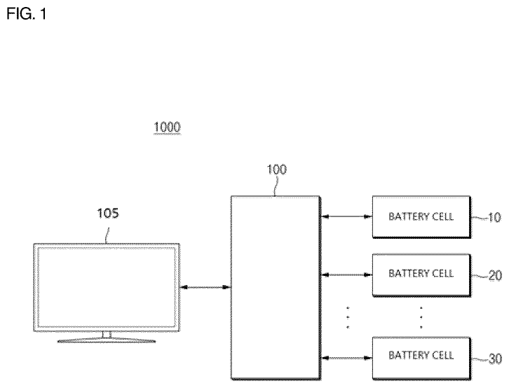

FIG. 1 is a conceptual view illustrating a battery deterioration detection system according to one embodiment disclosed herein.

Referring to FIG. 1, a battery deterioration detection system 1000 may include a battery deterioration detection device 100 and the like. However, it is only an exemplary embodiment for achieving the object of the present invention, and it is obvious that some components may be added or omitted as needed. In addition, components of the battery deterioration detection system 1000 illustrated in FIG. 1 represents functionally distinct functional elements, and it should be noted that a plurality of components may be implemented in an integrated form in an actual physical environment.

In the battery deterioration detection system 1000, the battery deterioration detection device 100 is a computing device for providing a battery deterioration detection service to a user by measuring deterioration detection information about a plurality of battery cells 10, 20, and 30 and providing the measured deterioration detection information to the user. Here, the computing device may be a notebook, a desktop, a laptop, or the like, but is not limited thereto, and may include any type of device having a computing function and a communication function. However, when the battery deterioration detection service is provided to many users, the battery deterioration detection device 100 may be preferably implemented as a high-performance server computing device.

The battery deterioration detection device 100 may acquire various types of data from the battery cells 10, 20, and 30. According to an embodiment, various types of data acquired may be used by the battery deterioration detection device 100 to detect the deterioration of each of the battery cells 10, 20, and 30. For example, the battery deterioration detection device 100 may acquire deterioration detection information and/or log data from at least one of the battery cells 10, 20, and 30.

The deterioration detection information may be information about the characteristics of each battery cell. The deterioration detection information may include information about a voltage, current, and temperature of the battery cell. The log data may be data according to the operation of each battery cell. The log data may include data on at least one of the operating state of charge (SOC), depth of discharge (DOD), and discharge amount.

According to an embodiment of the present invention, the battery deterioration detection device 100 may acquire deterioration detection information and log data for the battery cells 10, 20, and 30 through various wired or wireless networks.

The battery deterioration detection device 100 may generate an estimated value of each of the battery cells 10, 20, and 30 using the acquired deterioration detection information and/or log data. The estimated value may include at least one of the SOC and a state of health (SOH).

The battery deterioration detection device 100 may determine whether to diagnose deterioration abnormality of the battery based on at least one of the estimated value of each of the battery cells 10, 20, and 30, information about an on or off state of the battery, a stop holding time after a mobile device (e.g., a vehicle, an electric vehicle, and the like) is stopped, and/or deterioration detection information of each of the plurality of cells.

The battery deterioration detection device 100 may perform a deterioration abnormal diagnosis operation on the battery based on the determined deterioration abnormal diagnosis. According to an embodiment, the battery deterioration detection device 100 may display the result of performing the deterioration abnormal diagnosis operation on a display unit 105.

In the battery deterioration detection system 1000, the display unit 105 may be a terminal of a user receiving a battery deterioration detection service. The terminal of the user may be a display for communicating with the battery deterioration detection device 100 in a wired and/or wireless communication manner.

The battery deterioration detection device 100 may display the result of performing the deterioration abnormal diagnosis operation on each of the battery cells 10, 20, and 30 through the display unit 105. According to an embodiment, the battery deterioration detection device 100 may generate a group for a plurality of cells through the display unit 105 and display the result of performing the deterioration abnormal diagnosis operation through the group.

The components of the battery deterioration occurrence detection system 1000 may communicate with each other through a network. Here, the network may be implemented as any type of wired/wireless network such as a local area network (LAN), a wide area network (WAN), a mobile radio communication network, Wibro (Wireless Broadband Internet), or the like.

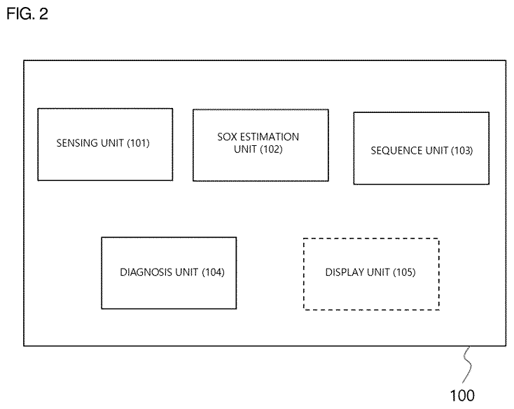

Until now, the battery deterioration detection system 1000 according to one embodiment of the present invention has been described with reference to FIG. 1. Hereinafter, the configuration and operation of the battery deterioration detection device 100 according to one embodiment of the present invention will be described with reference to FIGS. 2 to 8.

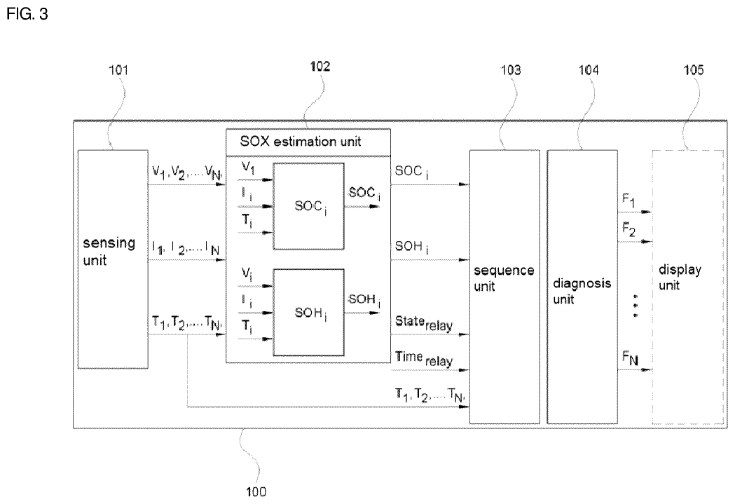

FIG. 2 is a block diagram showing the battery deterioration detection device 100 according to one embodiment of this document. FIG. 3 is a conceptual diagram illustrating an operation flow between components of the battery deterioration detection device 100 according to one embodiment of this document. Hereinafter, description thereof will be given with reference to FIGS. 2 to 3.

Referring to FIGS. 2 and 3, the battery deterioration detection device 100 according to one embodiment disclosed herein may include a sensing unit 101 (e.g., a sensor), a SOX estimation unit 102 (e.g., a SOX estimator; SOX being a shorthand for referring to both SOC and SOH together), a sequence unit 103 (e.g., a sequencer), a diagnosis unit 104 (e.g., a diagnoser), and/or the display unit 105 (e.g., a display). Hereinafter, the battery deterioration detection device 100 according to some embodiments will be described with reference to FIG. 3. A controller (e.g., a processor, a microcontroller unit (MCU), etc.) may control one or more of the sensing unit 101, the SOX estimation unit 102, the sequence unit 103, the diagnosis unit 104, and the display unit 105.

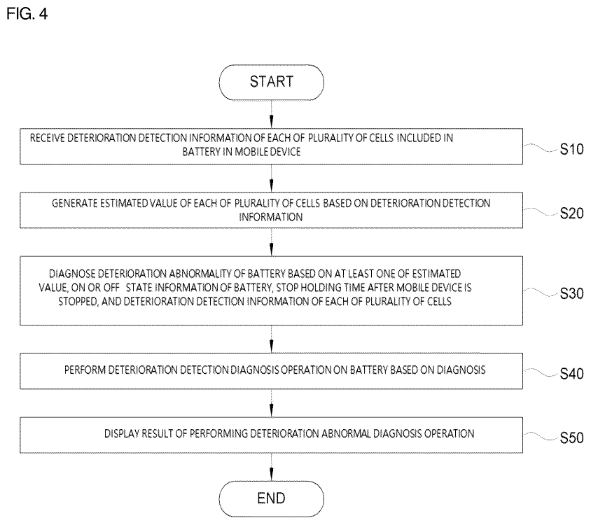

FIG. 4 is a flowchart illustrating a method of operating a battery deterioration detection device according to one embodiment disclosed herein.

Referring to FIGS. 3 and 4, a method of operating a battery deterioration detection device according to one embodiment disclosed herein senses deterioration detection information of each of a plurality of cells included in a battery in a mobile device through the sensing unit 101 (S10).

In this case, the deterioration detection information sensed by the sensing unit 101 of each of the plurality of cells included in the battery in the mobile device may include, for example, voltages V1, V2, . . . , and VN, currents I1, I2, . . . , and IN, and temperatures T1, T2, . . . , and TN of each of the plurality of cells. N is a natural number and may be the number of cells included in the battery in the mobile device.

Thereafter, based on the deterioration detection information, an estimated value of each of the plurality of cells is generated through the SOX estimation unit 102 (S20).

In this case, the estimated value generated by the SOX estimation unit 102 may be, for example, an SOC (remaining capacity of a battery/total capacity) and an SOH (a life of a battery).

More specifically, the SOX estimation unit 102 includes an SOC (SOCᵢ) calculation block and an SOH (SOHᵢ) calculation block. Each block may calculate SOCs (SOC₁, SOC₂, . . . , and SOC_{N}) and SOHs (SOH₁, SOH₂, . . . , and SOH_{N}) of each of the plurality of cells based on deterioration detection information (voltages V₁, V₂, . . . , and V_{N}), currents I₁, I₂, . . . , and I_{N}, and temperatures T₁, T₂, . . . , and T_{N}) of each of the plurality of cells included in the battery in the mobile device.

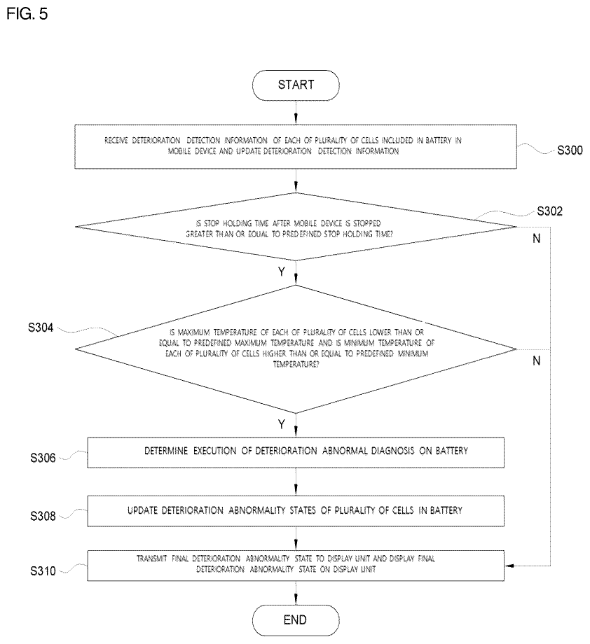

Thereafter, through the sequence unit 103, the SOX estimation unit 102 determines whether to diagnose deterioration abnormality of the battery based on at least one of the estimated values SOCᵢ and SOHᵢ (i is any natural number from 1 to N), the on or off state information Staterelay of the battery, a stop holding time Timerest after the mobile device is stopped, and deterioration detection information (temperatures T₁, T₂, . . . , and T_{N}) of each of the plurality of cells (S30). A specific operation of the sequence unit 103 will be described with reference to FIG. 5 below.

FIG. 5 is a view illustrating a method of operating a sequence unit according to one embodiment disclosed herein.

Referring to FIGS. 3 and 5, the sequence unit 103 receives and updates the deterioration detection information (e.g., temperature T₁, T₂, . . . , and T_{N}) of each of the plurality of cells included in the battery in the mobile device, and updates or renews the SOCs (SOC₁, SOC₂, . . . , and SOC_{N}) and the SOHs (SOH₁, SOH₂, . . . , and SOH_{N}), the on or off state information State_{relay} of the battery, and the stop holding time Timeᵣₑₛₜ after the mobile device is stopped (S300).

Thereafter, the sequence unit 103 checks that the on or off state information State_{relay} of the battery is on and determines whether the stop holding time Timeᵣₑₛₜ after the mobile device is stopped is greater than or equal to a predefined stop holding time (S302).

When the sequence unit 103 checks that the on or off state information State_{relay} of the battery is on and determines that the stop holding time Timeᵣₑₛₜ after the mobile device is stopped is greater than or equal to the predefined stop holding time (Y), the sequence unit 103 determines whether a temperature of a cell with the highest temperature among the plurality of cells included in the battery in the mobile device is lower than or equal to a predefined maximum temperature and a temperature of a cell with the lowest temperature is higher than or equal to a predefined minimum temperature (S304).

When the sequence unit 103 determines that the temperature of the cell with the highest temperature among the plurality of cells included in the battery in the mobile device is lower than or equal to the predefined maximum temperature and the temperature of the cell with the lowest temperature is higher than or equal to the predefined minimum temperature (Y), the sequence unit 103 determines the execution of deterioration abnormal diagnosis for the battery (S306). In this case, the diagnosis unit 104 receives an abnormal diagnosis execution instruction through the sequence unit 103 and performs deterioration abnormal diagnosis on the battery.

Thereafter, the sequence unit 103 updates a deterioration abnormal diagnosis result Fᵢ according to the plurality of cells included in the battery (S308).

The sequence unit 103 transmits a final deterioration abnormality state of the battery to the display unit 105, and the display unit 105 displays the final deterioration abnormality state (S310).

When conditions in operations S302 and S304 are not satisfied (N), the sequence unit 103 does not perform an update on the deterioration abnormality states for the plurality of cells and instructs the display unit 105 to display current states.

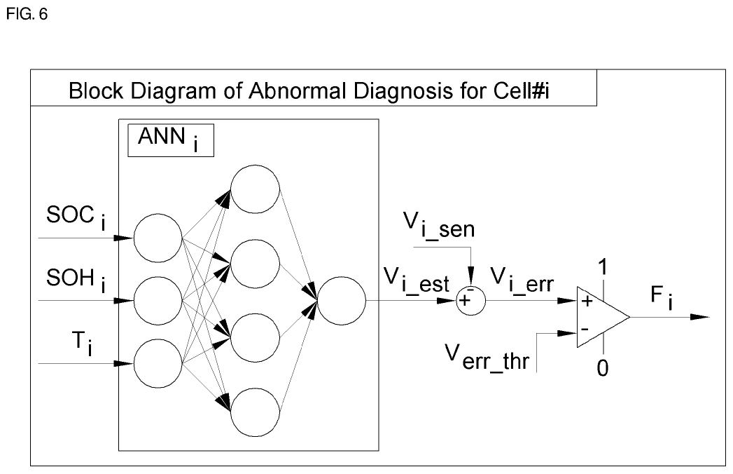

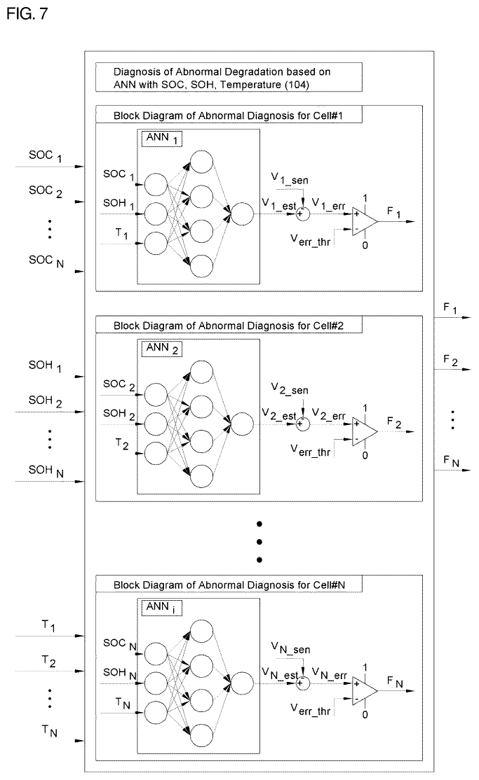

Referring back to FIGS. 3 and 4, the diagnosis unit 104 performs a deterioration abnormal diagnosis operation on the battery based on the diagnosis of the sequence unit 103 (S40). The operation of the diagnosis unit 104 performing deterioration abnormal diagnosis on the battery will be described in detail with reference to FIGS. 6 and 7 below.

FIG. 6 is a view for describing an abnormal diagnosis block in a diagnosis unit according to one embodiment disclosed herein. FIG. 7 is a view for describing a diagnosis unit including a plurality of abnormal diagnosis blocks according to one embodiment disclosed herein.

Referring to FIGS. 6 and 7, the diagnosis unit 104 may include a plurality of abnormal diagnosis blocks of FIG. 6 as illustrated in FIG. 7.

Each abnormal diagnosis block includes a neural network model which uses estimated values SOCᵢ and SOHᵢ and temperature information Tᵢ as an input. It is obvious that the neural network model may be, for example, an artificial neural network (ANN), a deep neural network (DNN), a convolution neural network (CNN), or a recurrent neural network (RNN). The following description will be given as an example assuming that the neural network model included in each of the abnormal diagnosis blocks of the present invention is an ANN.

The neural network model generates an estimated open circuit voltage (OCV) value V_{i_est}.

Thereafter, the diagnosis unit 104 calculates a difference between the estimated OCV value V_{i_est} and a sensing voltage value V_{i_sen} sensed through the sensing unit 101 through an adder and generates an estimated error value V_{i_err}.

Thereafter, the diagnosis unit 104 outputs the abnormal deterioration state Fᵢ for an i^{th} cell in the battery through an amplifier which receives the estimated error value V_{i_err} at a (+) terminal and receives a predetermined threshold estimated error value V_{err_thr} at a (−) terminal.

Through such a method, the diagnostic unit 104 may output abnormal deterioration states F₁ to F_{N} for all cells from 1 to N.

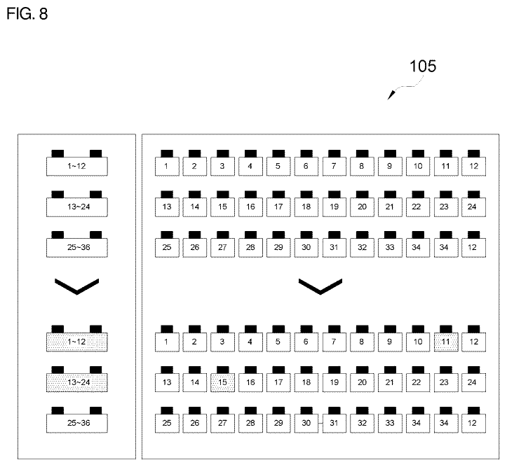

Referring back to FIGS. 3 and 4, the display unit 105 displays the result of performing the abnormal deterioration diagnosis operation (S50). A specific operation of the display unit 105 will be described with reference to FIG. 8.

FIG. 8 is a view for describing a display unit according to one embodiment disclosed herein. The method in which the display unit 105 outputs the abnormal deterioration states F₁ to F_{N} for all cells is illustrative, and the present invention is not limited to FIG. 8. Hereinafter, an example in which the display unit 105 displays an abnormal deterioration state for a battery including 36 cells will be described.

The display unit 105 may output an abnormal deterioration state, for example, in a manner in which 36 cells are divided into 3 groups each including 12 cells and a group including a cell in which abnormal deterioration has occurred is displayed as abnormal.

For example, referring to FIG. 8, the display unit 105 may output the abnormal deterioration state in a manner in which a first group (Cells 1 to 12) and a second group (Cells 13 to 24), which include the cells (Cells 11 and 15) in which abnormal deterioration has occurred among the three groups each including 12 cells, may be distinguished from the third group (Cells 25 to 36) which is a normal group.

The method of separately displaying the cells in which abnormal deterioration has occurred may include various methods such as, for example, changing the shape of the outline, changing the size of the group, changing the color, and the like.

According to an embodiment, the display unit 105 may output the abnormal deterioration state so that whether abnormal deterioration of each of the 36 cells occurs may be recognized.

For example, referring to FIG. 8, the display unit 105 may output the abnormal deterioration state in a manner in which the cells (Cells 11 and 15) in which abnormal deterioration has occurred among the three groups each including 12 cells may be displayed to be distinguished from the normal cells.

The method of separately displaying the cells in which abnormal deterioration has occurred may include various methods such as, for example, changing the shape of the outline, changing the size of the group, changing the color, and the like.

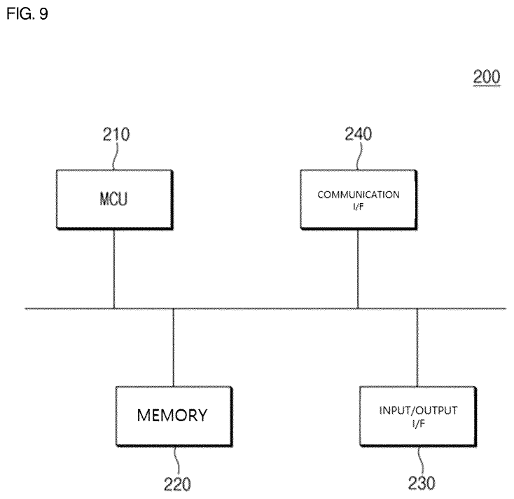

FIG. 9 is a view illustrating a computing system according to another embodiment disclosed herein.

Referring to FIG. 9, a computing system 200 according to one embodiment disclosed herein may include a micro controller unit (MCU) 210, a memory 220, an input/output I/F 230, and a communication I/F 240.

The MCU 210 may be a processor for executing various types of programs (e.g., an SOX calculation program, a program which determines whether to perform deterioration abnormal diagnosis on a battery, and the like) stored in the memory 220, processing various types of data including SOCs, SOHs, and the like of a plurality of battery cells through these programs, and performing functions of the battery deterioration detection unit 100 described above with reference to FIGS. 1 to 3 or may be a processor for executing the battery deterioration detection method described above with reference to FIG. 4.

The memory 220 may store various types of programs related to the SOX estimation program of the battery cell and the program for determining whether to perform deterioration abnormal diagnosis on the battery. In addition, the memory 220 may store various types of data such as SOC data, log data, and/or deterioration detection information of each battery cell.

The memory 220 may be provided as a plurality of memories as needed. The memory 220 may be a volatile memory or a non-volatile memory. As the memory 220 of the volatile memory, a RAM, a DRAM, an SRAM, or the like may be used. As the memory 220 of the non-volatile memory, a ROM, a PROM, an EAROM, an EPROM, an EEPROM, a flash memory, or the like may be used. The examples of the listed memories 220 are merely illustrative and are not limited to these examples.

The input/output I/F 230 may be an interface for connecting an input device (not illustrated), such as a keyboard, a mouse, or a touch panel, and an output device, such as a display (not shown) with the MCU 210 and allowing the input and output devices and the MCU 210 to transmit and receive data.

The communication I/F 230 is a component capable of transmitting and receiving various types of data to and from the server and may be various devices capable of supporting wired or wireless communication. For example, a program, various types of data, or the like for calculating an increase in energy or measuring the remaining capacity may be transmitted and received from a separately provided external server through the communication I/F 230.

As described above, the battery deterioration detection method according to one embodiment disclosed herein may be stored in the memory 220 and executed by the MCU 210.

According to the battery deterioration detection device and the method thereof according to the embodiments disclosed herein, it is possible to detect abnormal deterioration by accurately estimating the state of the battery.

According to the battery deterioration detection device and the method thereof according to the embodiments disclosed herein, it is possible to detect abnormal deterioration by accurately estimating the state of the battery during initial operation of the battery.

According to the battery deterioration detection device and the method thereof according to the embodiments disclosed herein, it is possible to prevent accidents due to thermal runaway by notifying the user of detected abnormal deterioration of the battery.

The above description is merely the exemplary description of the technical spirit disclosed herein, and those skilled in the art to which embodiments disclosed herein pertain will be able to variously modify and change the present document without departing from the essential characteristics of the embodiments disclosed herein.

Therefore, the embodiments disclosed herein are not intended to limit the technical spirit disclosed herein, but for describing it, and the scope of the technical spirit disclosed herein is not limited by these embodiments. The scope of the technical spirit disclosed herein should be construed by the appended claims, and all technical spirits within the equivalent range should be construed as being included in the scope of this document.

What is claimed is:

1. A battery deterioration detection device, comprising:
a sensor configured to sense deterioration detection information of each of a plurality of cells included in a battery of a mobile device;
an SOX estimator configured to generate an estimated value of each of the plurality of cells based on the deterioration detection information;
a sequencer configured to determine whether to perform deterioration abnormal diagnosis on the battery based on at least one of the estimated value generated by the SOX estimator, an on or off state information of the battery, a stop holding time after the mobile device is stopped, and deterioration detection information of each of the plurality of cells; and
a diagnoser configured to perform a deterioration abnormal diagnosis operation on the battery based on the diagnosis of the sequencer.

2. The battery deterioration detection device of claim 1, further comprising:
a display configured to display a result of performing the deterioration abnormal diagnosis operation by the diagnoser.

3. The battery deterioration detection device of claim 2, wherein the display is configured to, at least one of:
display a result of performing the deterioration abnormal diagnosis operation on each of the plurality of cells; or
generate a group for the plurality of cells and display the result of performing the deterioration abnormal diagnosis operation through the group; or
a combination thereof.

4. The battery deterioration detection device of claim 1, wherein the deterioration detection information of each of the plurality of cells sensed by the sensor includes a voltage, current, and temperature of each of the plurality of cells.

5. The battery deterioration detection device of claim 4, wherein the sequencer is further configured to:
determine that a maximum temperature of each of the plurality of cells is lower than or equal to a predefined maximum temperature and a minimum temperature of each of the plurality of cells is higher than or equal to a predefined minimum temperature in response to a determination that the stop holding time is greater than or equal to a predefined stop holding time; and
determine the execution of deterioration abnormal diagnosis of the battery.

6. The battery deterioration detection device of claim 1, wherein the estimated value generated by the SOX estimator includes at least one of a state of charge (SOC) and a state of health (SOH).

7. The battery deterioration detection device of claim 6, wherein the diagnoser generates an estimated open circuit voltage (OCV) value of each of the plurality of cells through a neural network model which receives the estimated value and temperature of each of the plurality of cells as an input.

8. The battery deterioration detection device of claim 7, wherein the diagnoser calculates a difference between the estimated OCV value and a voltage value sensed by the sensor and generates an estimated error value.

9. The battery deterioration detection device of claim 8, wherein the diagnoser receives the estimated error value and a predetermined threshold estimated error value and generates a result of performing the deterioration abnormal diagnosis operation on each of the plurality of cells in the battery.

10. A method of operating a battery deterioration detection device, the method comprising:
sensing deterioration detection information of each of a plurality of cells included in a battery in a mobile device through a sensor;
generating an estimated value of each of the plurality of cells based on the deterioration detection information through an SOX estimator;
determining whether to perform deterioration abnormal diagnosis on the battery based on at least one of the estimated value generated by the SOX estimator, an on or off state information of the battery, a stop holding time after the mobile device is stopped, and deterioration detection information about each of the plurality of cells through a sequencer;
performing a deterioration abnormal diagnosis operation on the battery based on the diagnosis of the sequencer through a diagnoser; and
displaying a result of performing a deterioration abnormal diagnosis operation of the diagnoser through a display.

11. A battery deterioration detection device for a vehicle, the battery detection device comprising:
a sensor to sense each of a plurality of cells included in a battery of the vehicle;
an SOX estimator to generate an estimated value of each of the plurality of cells;
a sequencer to determine whether to perform a deterioration abnormal diagnosis on the battery;
a diagnoser to perform a deterioration abnormal diagnosis operation on the battery; and
a controller configured to:
control the sensor to sense deterioration detection information of each of the plurality of cells;
control the SOX estimator to generate the estimated value of each of the plurality of cells based on the deterioration detection information;
control the sequencer to determine whether to perform the deterioration abnormal diagnosis on the battery based on at least one of the estimated value generated by the SOX estimator, an on or off state information of the battery, a stop holding time after the vehicle is stopped, and deterioration detection information of each of the plurality of cells; and
control the diagnoser to perform the deterioration abnormal diagnosis operation on the battery based on the diagnosis of the sequencer.

12. The battery deterioration detection device of claim 11, further comprising:
a display,
wherein the controller is further configured to control the display to display a result of performing the deterioration abnormal diagnosis operation by the diagnoser.

13. The battery deterioration detection device of claim 12, wherein the controller is further configured to control the display to, at least one of:
display a result of performing the deterioration abnormal diagnosis operation on each of the plurality of cells; or
generate a group for the plurality of cells and display the result of performing the deterioration abnormal diagnosis operation through the group; or
a combination thereof.

14. The battery deterioration detection device of claim 11, wherein the deterioration detection information of each of the plurality of cells sensed by the sensor includes a voltage, current, and temperature of each of the plurality of cells.

15. The battery deterioration detection device of claim 14, wherein the controller is further configured to control the sequencer to:
determine that a maximum temperature of each of the plurality of cells is lower than or equal to a predefined maximum temperature and a minimum temperature of each of the plurality of cells is higher than or equal to a predefined minimum temperature in response to a determination that the stop holding time is greater than or equal to a predefined stop holding time; and
determine the execution of deterioration abnormal diagnosis of the battery.

16. The battery deterioration detection device of claim 11, wherein the estimated value generated by the SOX estimator includes at least one of a state of charge (SOC) and a state of health (SOH).

17. The battery deterioration detection device of claim 16, wherein the controller is further configured to control the diagnoser to generate an estimated open circuit voltage (OCV) value of each of the plurality of cells through a neural network model which receives the estimated value and temperature of each of the plurality of cells as an input.

18. The battery deterioration detection device of claim 17, wherein the controller is further configured to control the diagnoser to calculate a difference between the estimated OCV value and a voltage value sensed by the sensor and generates an estimated error value.

19. The battery deterioration detection device of claim 18, wherein the controller is further configured to control the diagnoser to:
receive the estimated error value and a predetermined threshold estimated error value; and
generate a result of performing the deterioration abnormal diagnosis operation on each of the plurality of cells in the battery.
